(19) United States
(12) Patent Application Publication
(10) Pub. No.: US 2013/0058015 A1
(43) Pub. Date: Mar. 7, 2013

(54) DISPLAY DEVICE

(71) Applicants: KUO-CHAN PENG, PINGZHEN CITY (TW); CHING-FENG HSIEH, TAIPEI CITY (TW)

(72) Inventors: KUO-CHAN PENG, PINGZHEN CITY (TW); CHING-FENG HSIEH, TAIPEI CITY (TW)

(73) Assignees: ASKEY COMPUTER CORP.; ASKEY TECHNOLOGY (JIANGSU) LTD.

(21) Appl. No.: 13/270,282

(22) Filed: Oct. 11, 2011

(30) Foreign Application Priority Data
Sep. 2, 2011 (TW) 100131768

(51) Int. Cl. H05K 7/00

(52) U.S. Cl. 361/679.01

(57) ABSTRACT

A display device for enlarging or extending a view of a handheld electronic device includes a body, a displaying unit, a second transmitting unit, a carrying unit, and a fixing unit. The fixing unit fixes the handheld electronic device to the carrying unit regardless of the dimensions of the handheld electronic device. The body and the carrying unit are coupled together by a coupling unit in a manner that the body and the carrying unit can move relative to each other, such that screens of the handheld electronic device and the display device lie in parallel or side by side to face a user. The display device can further include a touch control unit whereby the display device and the handheld electronic device demonstrate versatility through their display and touch control functions.

### CROSS-REFERENCE TO RELATED APPLICATION

This non-provisional application claims priority under 35 U.S.C. §119(a) on Patent Application No(s). 100131768 filed in Taiwan, R.O.C. on Sep. 2, 2011, the entire contents of which are hereby incorporated by reference.

### FIELD OF TECHNOLOGY

The present invention relates to display devices, and more particularly, to a display device applicable to a handheld electronic device mutually.

### BACKGROUND

Among mainstream consumer electronic products, smartphones and tablet PCs have their respective edges and thus have gained their respective slices of market share. Smartphones differ from tablet PCs in terms of dimensions, specifications, and performance Smartphones are lightweight, thin, compact, and readily portable. Tablet PCs feature a large display screen and thus are conducive to working, entertainment, and surfing the Internet. Consumers choose between smartphones and table PCs according to the need for portability and large display screens.

Due to their susceptibility to limitations of internal space and dependence on available technology, cell phones used to be outperformed by tablet PCs and notebook computers. However, smartphones are becoming more robust and versatile because of recent technological development. To enhance ease of use, it is a trend for smartphones to have ever-increasing dimensions of a screen. The trend is, however, held in check by communication functions and portability. As a result, commercially available smartphones usually have a screen of a dimension less than five inches.

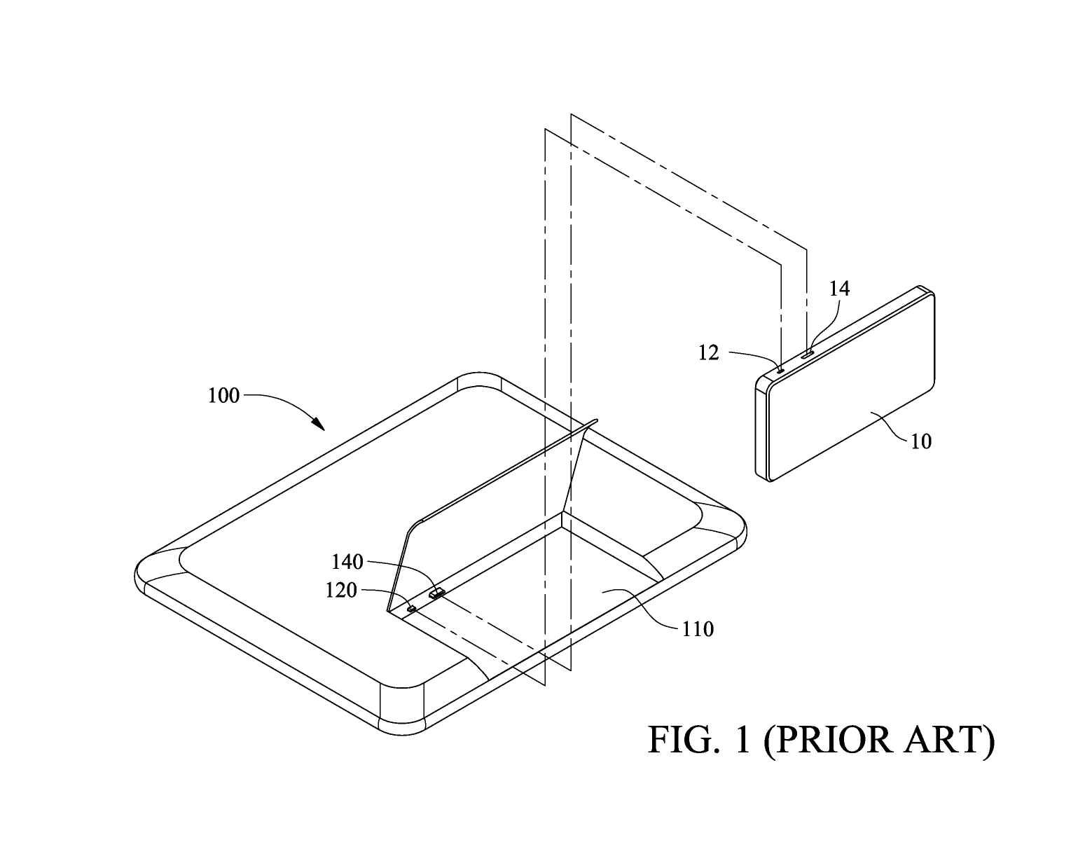

In addition to a large display screen, tablet PCs have an advantage of their similarity with smartphones in terms of functions and performance. This paves the way for the advent of a new product based on integration of tablet PCs and smartphones. Referring to FIG. 1, provided is a touch control monitor 100 capable of receiving a smartphone 10. A receiving chamber 110 is disposed on the rear side of the touch control monitor 100. Transmission jacks 120, 140 for transmitting and receiving signals are disposed at a sidewall of the receiving chamber 110. The transmission jacks 120, 140 correspond in position and category to transmission apertures 12, 14 on the smartphone 10. The transmission interface for the transmission jacks 120, 140 and the transmission apertures 12, 14 is usually a High-Definition Multimedia Interface (HDMI) or a Universal Serial Bus (USB) interface. Hence, the smartphone 10 can be received in the receiving chamber 110 of the touch control monitor 100, and the transmission jacks 120, 140 can be connected to the transmission apertures 12, 14, such that an audiovisual signal of the smartphone 10 can be displayed on the touch control monitor 100 by means of a HDMI transmission line to thereby enlarge the view of the smartphone 10 and send a control signal from the touch control monitor 100 to the smartphone 10 by means of a USB transmission line. In doing so, a user is able to use the smartphone 10 independently to meet the strict requirement of portability. Furthermore, it is feasible to combine the smartphone 10 and the touch control monitor 100 in order to bring about a large display screen.

Nonetheless, the touch control monitor 100 still has an unsolved disadvantage, that is, the application of the touch control monitor 100 is restricted to the smartphone 10 of specific model numbers, as opposed to all model numbers and all specifications, nor can the touch control monitor 100 be in use with other handheld electronic devices, because the receiving chamber 110 and the transmission jacks 120, 140 cannot work without conforming with the dimensions of the smartphone 10 and the positions and interface categories of the transmission apertures 12, 14.

With the smartphone 10 being received in the receiving chamber 110 on the rear side of the touch control monitor 100, it is impossible to access or operate the touch control monitor 100 and the smartphone 10 simultaneously. Normally, the smartphone 10 merely serves as a computation processing unit, and thus a portion of the functionality, such as display or touch control, of the smartphone 10 is not put to use, thereby reducing the applicability of the smartphone 10.

Hence, although the conventional integrated display device has both the merits of a handheld electronic device, such as a smartphone, and the merits of tablet PCs, it still has two unsolved disadvantages described hereunder. First, the application of the conventional integrated display device is restricted to the handheld electronic device of specific model numbers, as opposed to all model numbers and all specifications. Second, the handheld electronic device is disposed on the rear side or disposed inside the integrated display device, it is impossible to access or operate the touch control monitor and the smartphone simultaneously, thereby restricting the applicability of the display device.

### SUMMARY

It is an objective of the present invention to provide a display device applicable to any handheld electronic device of any model number and specifications, capable of carrying the handheld electronic device when in use, and capable of enlarging, extending, and displaying the view of the handheld electronic device.

Another objective of the present invention is to provide a display device, wherein the display views of the display device and a handheld electronic device are arranged in a parallel manner or side by side and displayed in the same direction to a user.

Yet another objective of the present invention is to provide a display device, wherein the user can access the display function and/or the touch control function of a displaying unit and the handheld electronic device, such that the display device manifest diverse applicability.

In order to achieve the above and other objectives, the present invention provides a display device for use with a handheld electronic device having a first transmitting unit. The handheld electronic device outputs at least an audiovisual signal. The display device comprises: a body; a displaying unit disposed on a side of the body; a second transmitting unit disposed on the body and electrically connected to the displaying unit and the first transmitting unit for receiving the audiovisual signal and displaying the audiovisual signal on the displaying unit; a carrying unit carrying the handheld electronic device and coupled to the body by a connecting unit such that the body and the carrying unit move relative to each other; and a fixing unit disposed on the carrying unit and comprising at least an adjusting member for adjusting the fixing unit such that the handheld electronic device is fixed in placed by the fixing unit.

In the display device, the connecting unit comprises a first protective panel, a bent portion, and a second protective panel. The body and the carrying unit are disposed on the first protective panel and the second protective panel, respectively. The bent portion enables the carrying unit and the body to rotate toward each other or rotate away from each other.

In the display device, a receiving space is disposed on another side of the body, wherein a guiding groove and a sliding element corresponding in position thereto are disposed at the receiving space and the connecting unit, respectively, for facilitating sliding of the carrying unit and sliding of the body relative to each other.

The present invention further provides a display device for use with a handheld electronic device having a first transmitting unit. The handheld electronic device outputs at least an audiovisual signal. The display device comprises: a body; a displaying unit disposed on a side of the body; a carrying unit carrying the handheld electronic device and coupled to the body by a connecting unit such that the body and the carrying unit move relative to each other; a second transmitting unit disposed on the carrying unit and electrically connected to the displaying unit and the first transmitting unit for receiving the audiovisual signal and displaying the audiovisual signal on the displaying unit; and a fixing unit disposed on the carrying unit and comprising at least an adjusting member for adjusting the fixing unit such that the handheld electronic device is fixed in place by the fixing unit.

In the display device, the carrying unit further comprises a receiving chamber, such that the fixing unit is received in the receiving chamber.

The display device further comprises a touch control unit disposed on the displaying unit and electrically connected to the second transmitting unit for generating a control signal, wherein the control signal is sent to the handheld electronic device via the second transmitting unit and the first transmitting unit.

In the display device, the fixing unit further comprises a plurality of clamping members connected to the adjusting member for adjusting the clamping members, such that the clamping members are drawn closer to each other to clamp and fix the handheld electronic device in place. The fixing unit comprises at least one clamping member. The clamping members are connected to the adjusting member for adjusting the clamping members in a manner that the handheld electronic device is jointly clamped and fixed by the clamping members and the sidewalls of the receiving chamber.

In the display device, signal transmission between the first transmitting unit and the second transmitting unit is effected by cable transmission or radio transmission. The cable transmission requires a transmission interface such as HDMI, VGA (Video Graphics Array), DVI (Digital Visual Interface), DisplayPort or USB interfaces. The radio transmission requires a transmission interface such as Bluetooth, Wi-Fi or NFC (Near Field Communication) interfaces.

Accordingly, the display device of the present invention can enlarge and extend the view of a handheld electronic device to the displaying unit, enable the display views of the display device and the handheld electronic device to lie in a parallel manner or side by side when in use and face the user, and enable the display device and the handheld electronic device to rotate toward each other or rotate away from each other, such that the user can access the touch control function and the display function of the displaying unit and the handheld electronic device concurrently to meet various user needs. The display device of the present invention further comprises a touch control unit whereby the user can access the display function and/or the touch control function of the display device and the handheld electronic device, such that the display device manifest diverse applicability.

### BRIEF DESCRIPTION

Objectives, features, and advantages of the present invention are hereunder illustrated with specific embodiments in conjunction with the accompanying drawings, in which:

FIG. 1 (PRIOR ART) is a schematic view of a conventional display device for displaying the view of a handheld electronic device;

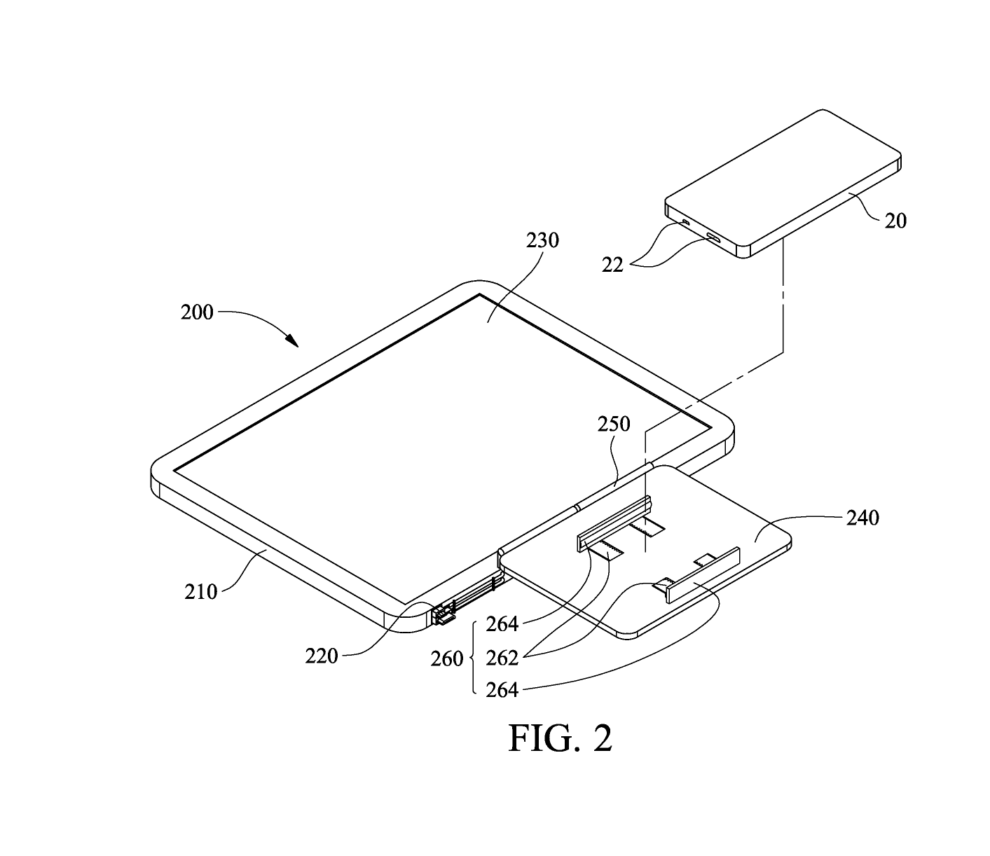

FIG. 2 is a schematic view of a display device according to the first embodiment of the present invention;

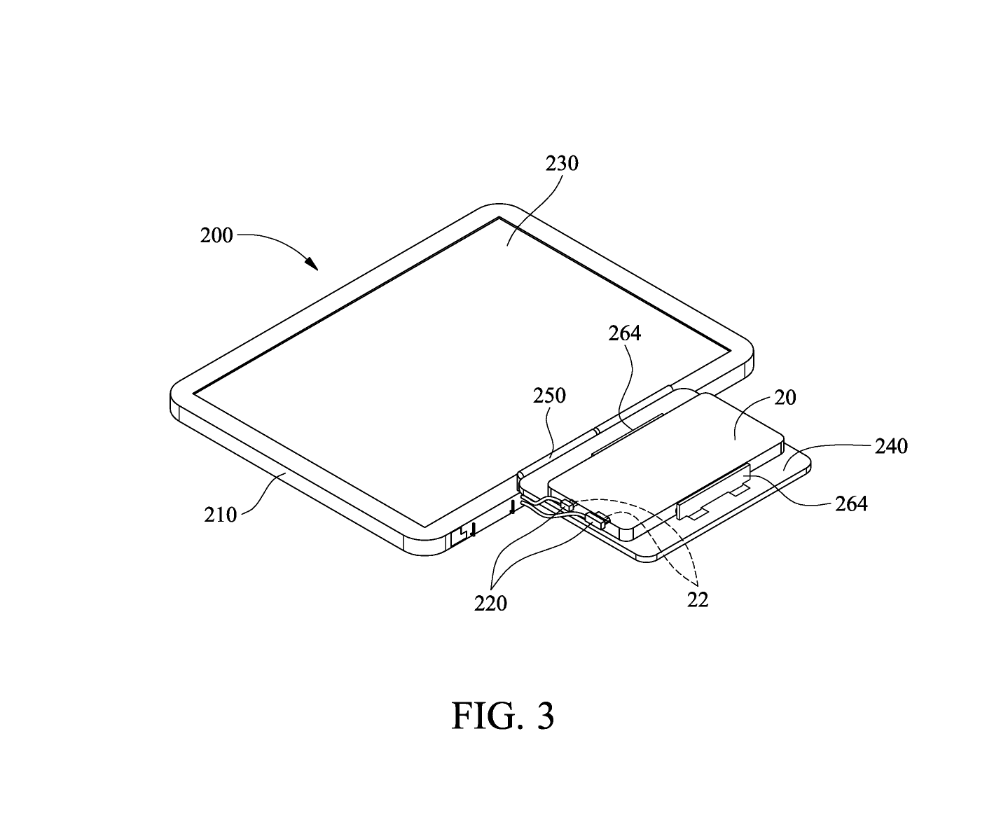

FIG. 3 is a schematic view of the display device having a handheld electronic device fixed thereto according to the first embodiment of the present invention;

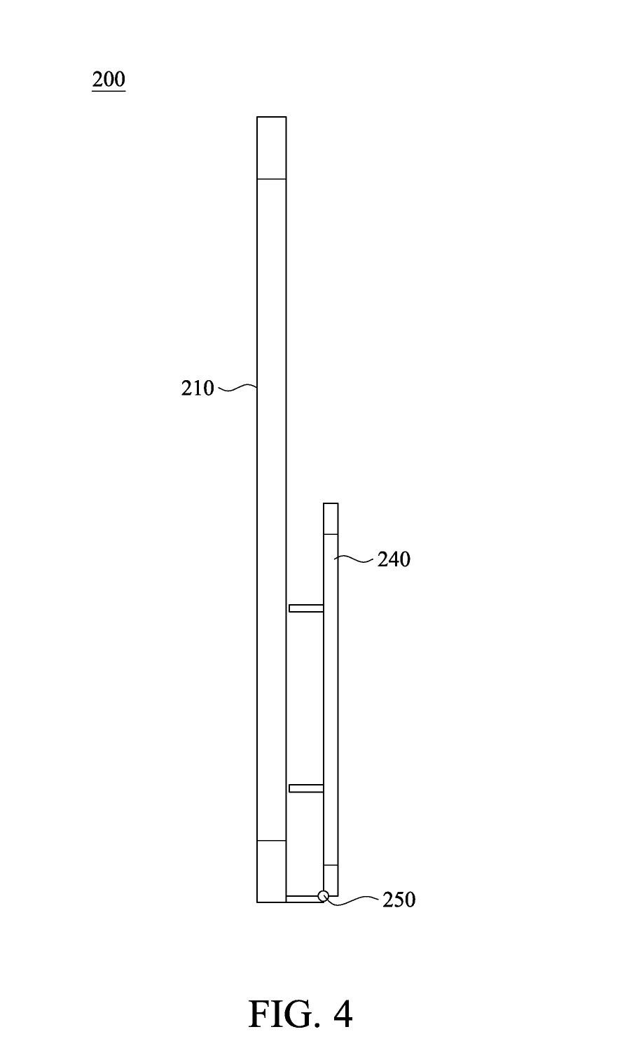

FIG. 4 is a schematic view of the display device having a carrying unit and a body which rotate and shut relative to each other according to the first embodiment of the present invention;

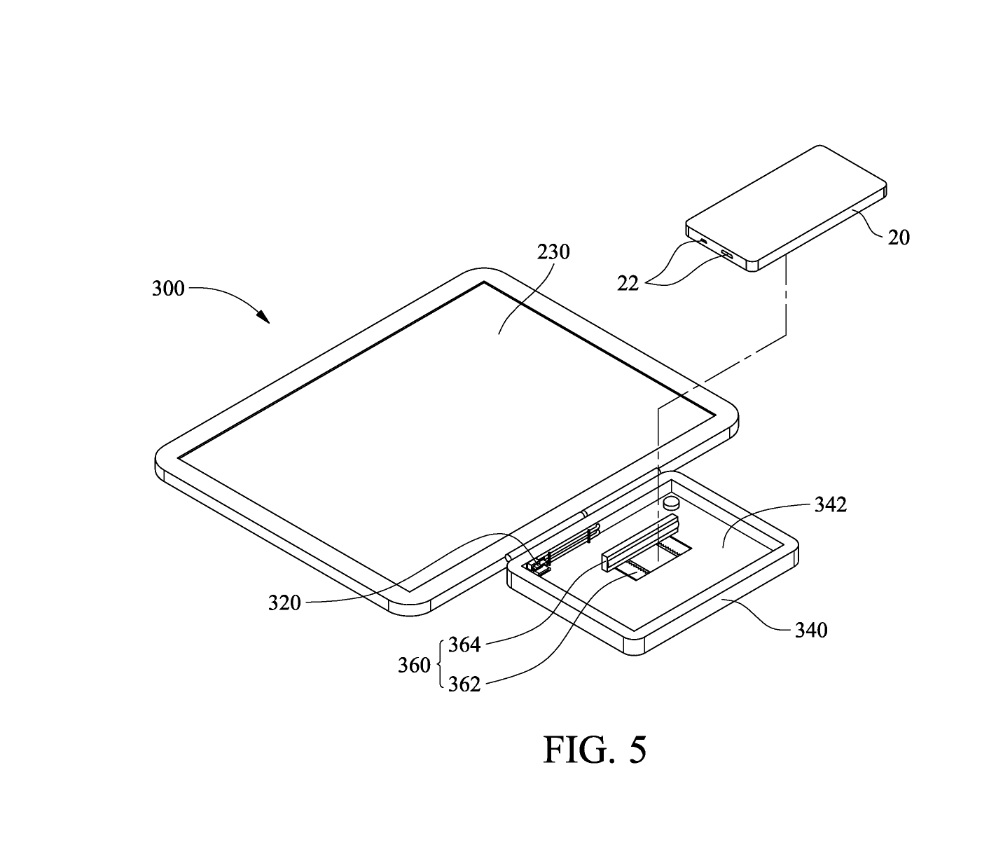

FIG. 5 is a schematic view of a display device according to the second embodiment of the present invention;

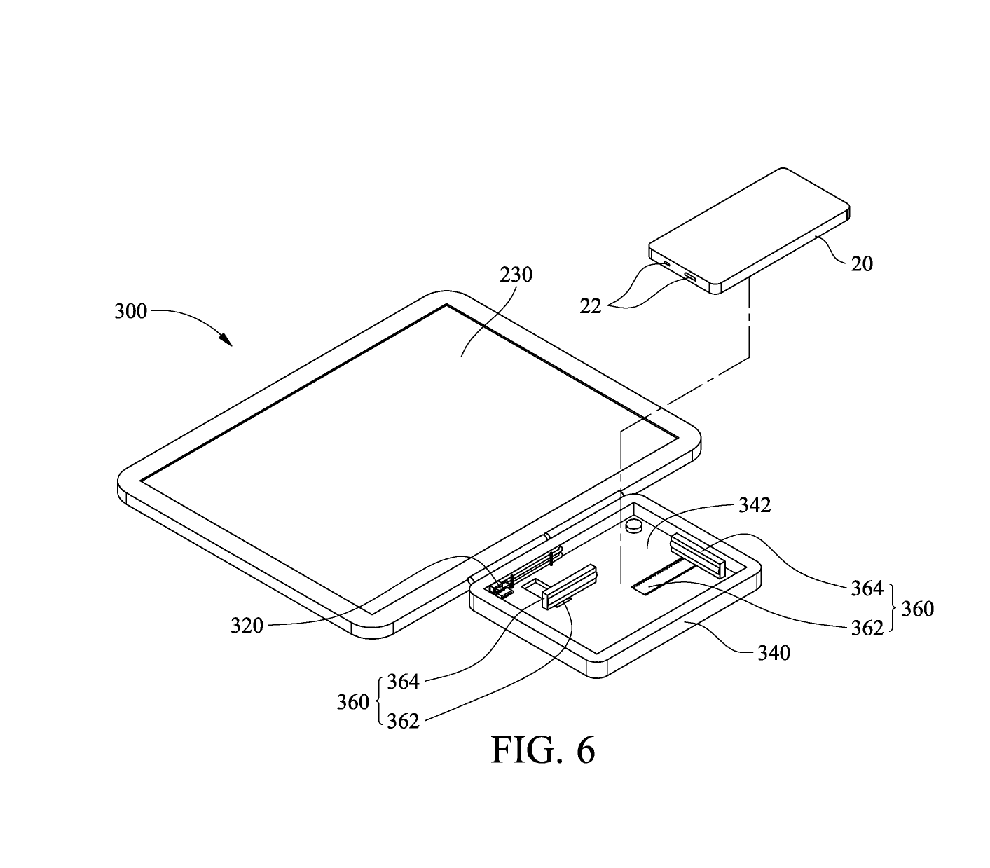

FIG. 6 is a schematic view of the display device comprising a receiving chamber having two clamping members therein according to the second embodiment of the present invention;

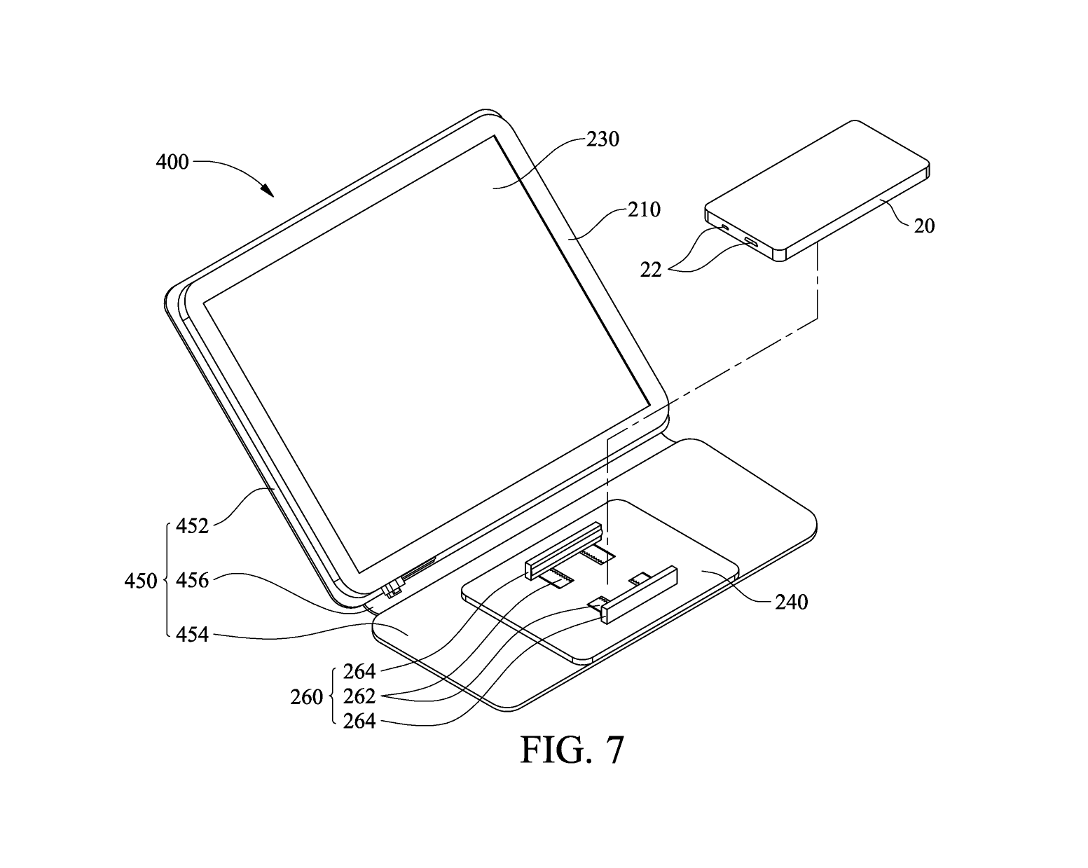

FIG. 7 is a schematic view of a display device according to the third embodiment of the present invention;

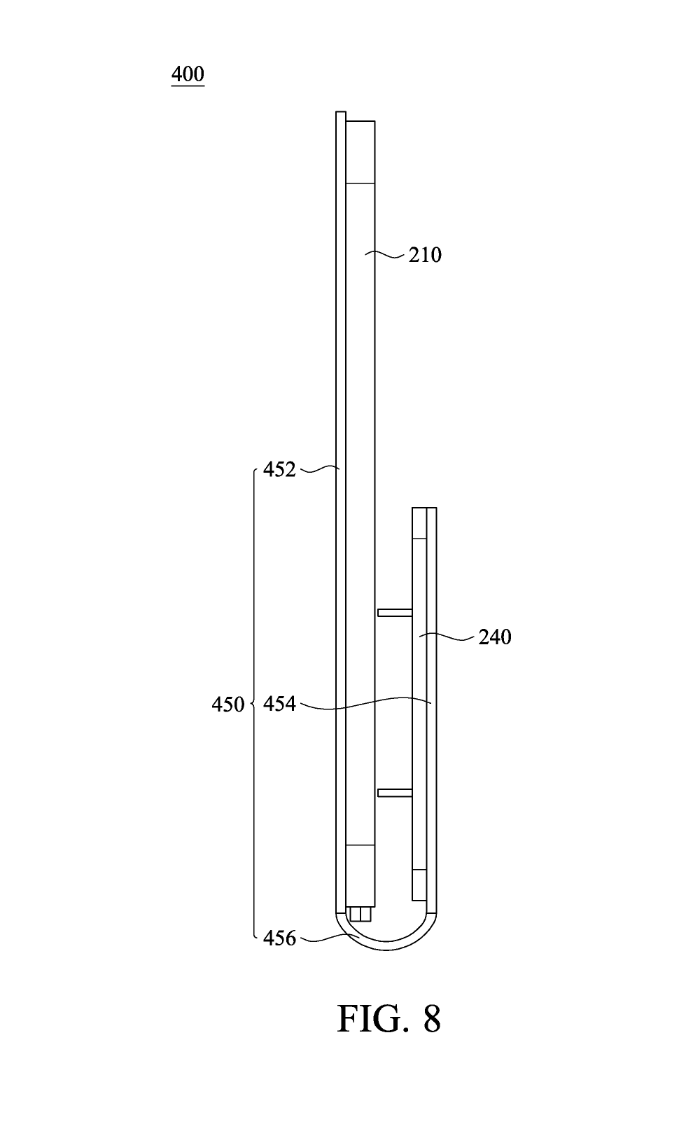

FIG. 8 is a schematic view of the display device having the carrying unit and the body which rotate and shut relative to each other according to the third embodiment of the present invention;

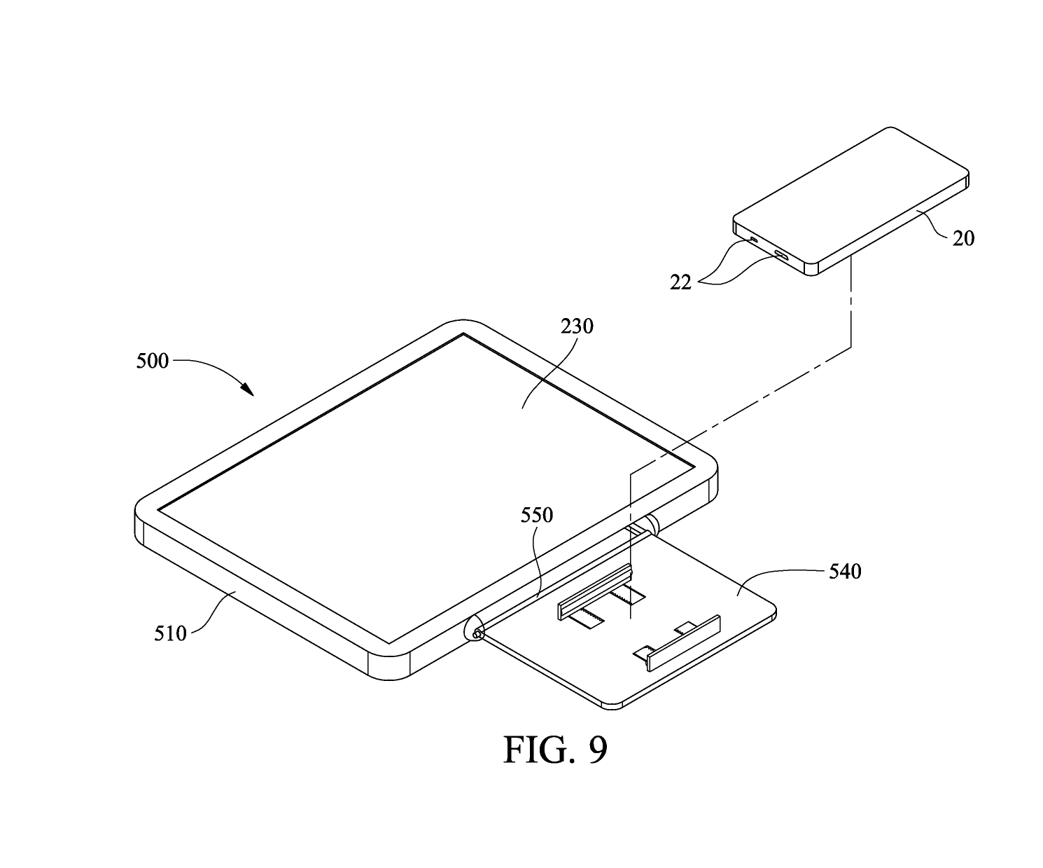

FIG. 9 is a schematic view of a display device according to the fourth embodiment of the present invention;

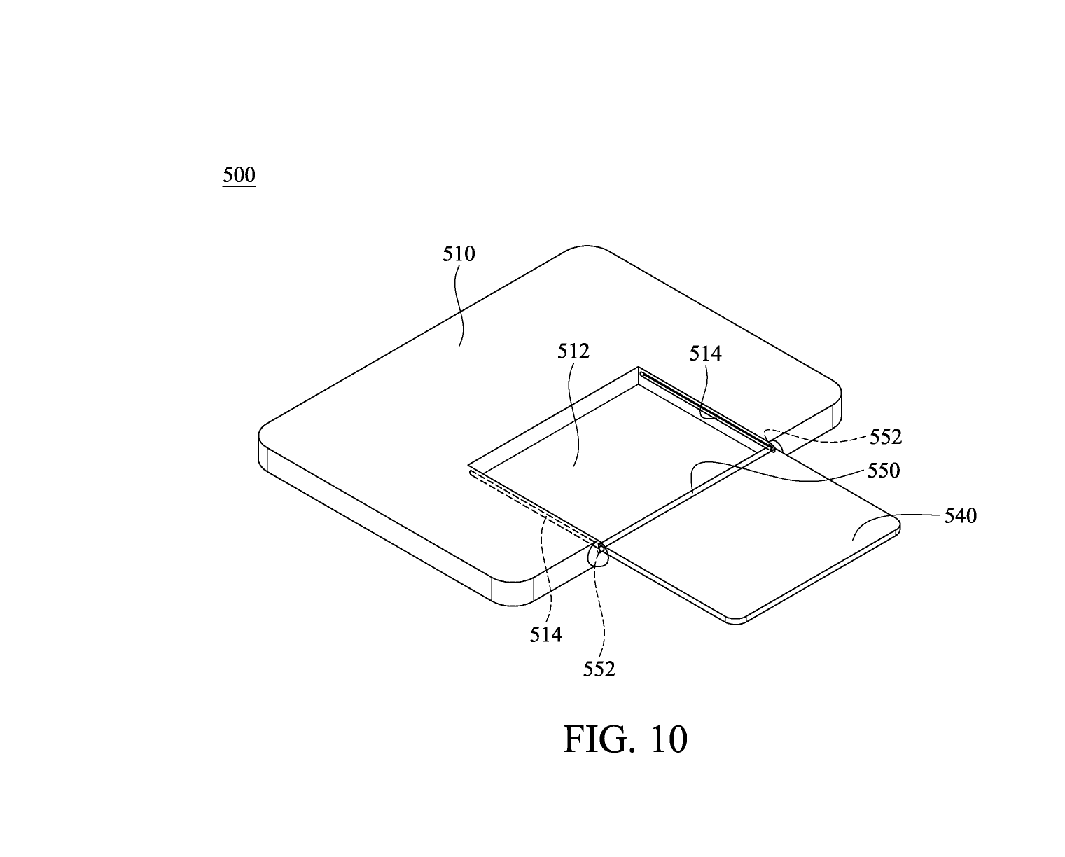

FIG. 10 is a schematic view of the bottom of a display device according to the fourth embodiment of the present invention;

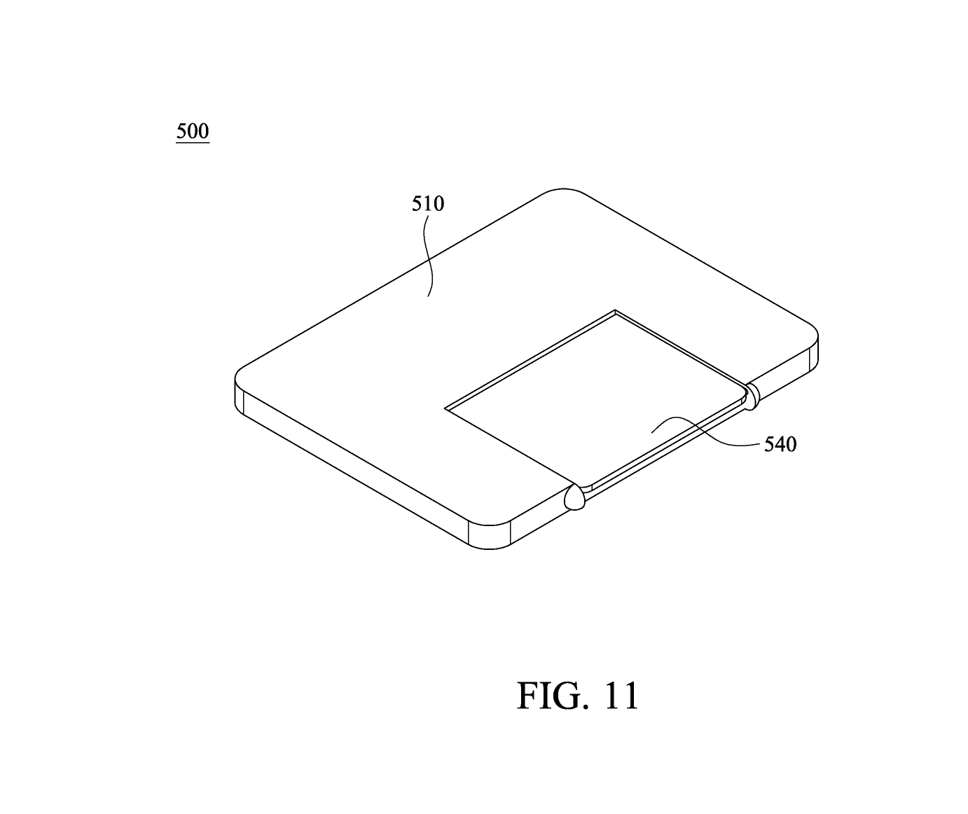

FIG. 11 is a schematic view of the display device storing the carrying unit in a receiving space at the bottom of the display device according to the fourth embodiment of the present invention;

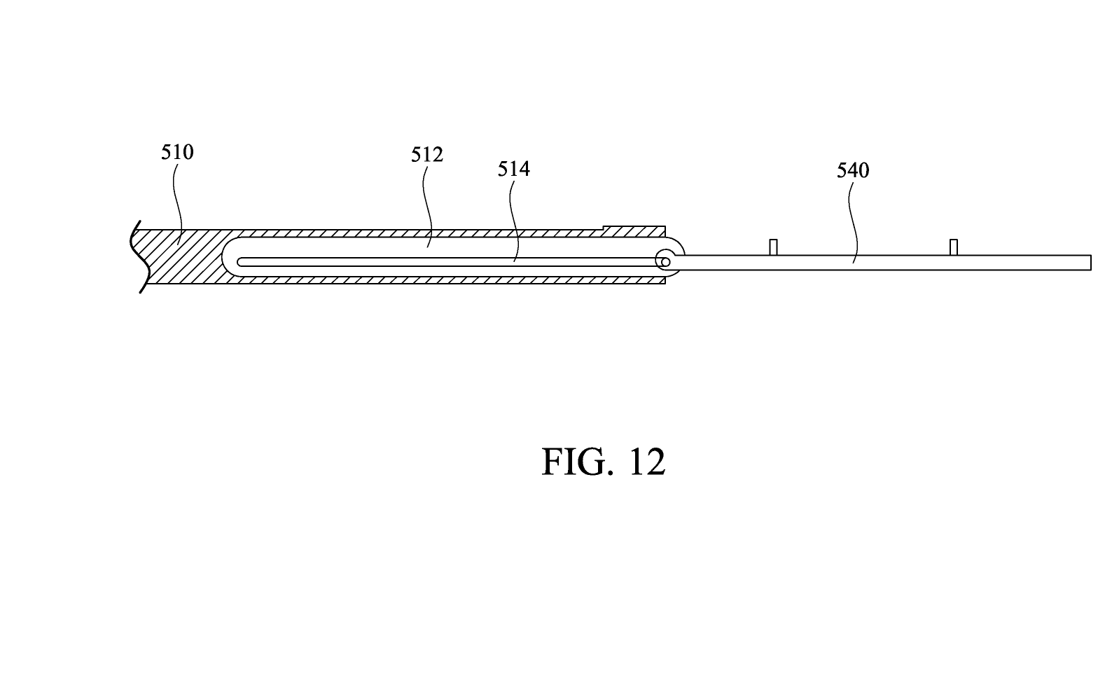

FIG. 12 is a schematic view of the display device, wherein an opening of the receiving space is disposed on one side of the body according to the fourth embodiment of the present invention;

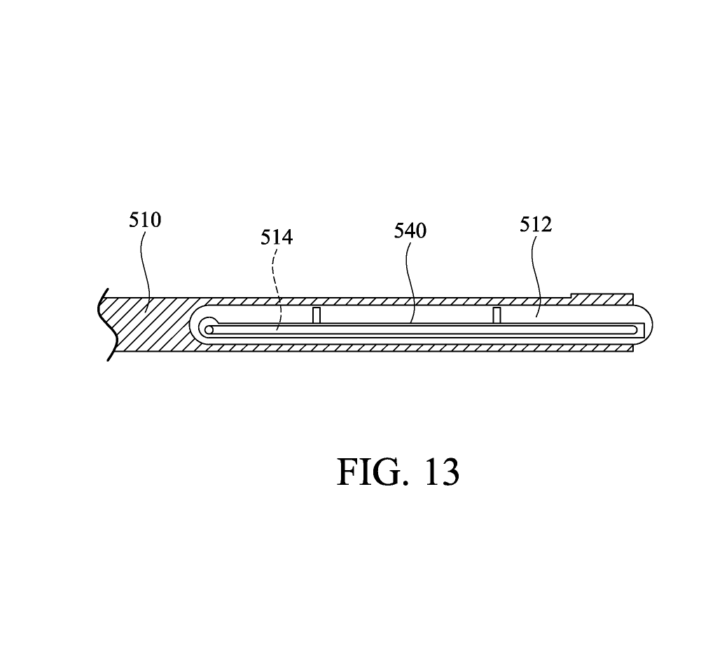

FIG. 13 is a schematic view of the carrying unit received in the receiving space of the display device in FIG. 12; and

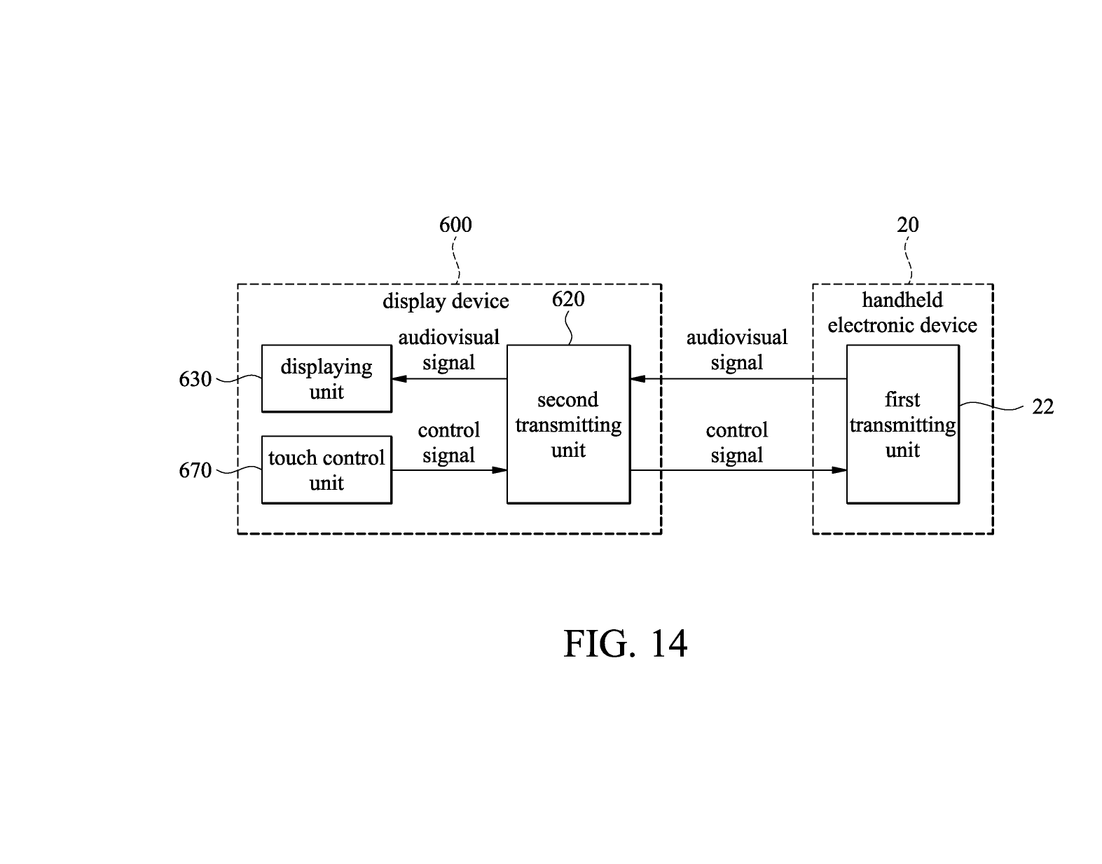

FIG. 14 is a schematic view of signal transmission between the display device and a handheld electronic device according to the fifth embodiment of the present invention.

### DETAILED DESCRIPTION

Referring to FIG. 2 through FIG. 4, there are shown schematic views of a display device 200 according to the first embodiment of the present invention. The display device 200 in the first embodiment of the present invention comprises a body 210, a displaying unit 230, a second transmitting unit 220, a carrying unit 240, and a fixing unit 260. The display device 200 is adapted to carry a handheld electronic device 20 and extend or enlarge its view. The handheld electronic device 20 has a first transmitting unit 22 for outputting an audiovisual signal. In this embodiment, the handheld electronic device 20 is exemplified by a smartphone but is not limited thereto. The display device 200 is adapted to enlarge or extend the view of any handheld electronic device equipped with an audiovisual transmission unit and a computation processing unit.

In the display device 200 of the present invention, the displaying unit 230 is disposed on one side of the body 210, and the second transmitting unit 220 is disposed on the body 210. The second transmitting unit 220 is electrically connected to the displaying unit 230 and the first transmitting unit 22, such that the audiovisual signal can be displayed on the displaying unit 230. The carrying unit 240 is adapted to carry the handheld electronic device 20, while the carrying unit 240 and the body 210 are coupled together by means of a connecting unit 250, such that the body 210 and the carrying unit 240 move relative to each other. The fixing unit 260 is disposed on the carrying unit 240. At least an adjusting member 262 is disposed on the carrying unit 240. The adjusting member 262 is adapted to adjust the fixing unit 260 such that the fixing unit 260 is fixed to the handheld electronic device 20. Hence, the display device 200 can carry the handheld electronic device 20 in a manner that the handheld electronic device 20 is positioned on one side of the body 210, and in consequence the view of the handheld electronic device 20 is extended, enlarged, and displayed on the displaying unit 230, while both the display device 200 and the handheld electronic device 20 face a user simultaneously and display their respective views. In a scenario where the handheld electronic device 20 is a smartphone having a touch control function, it is feasible to treat the handheld electronic device 20 as a keyboard or an input interface of touch control and thereby enable an operable view to be displayed on the displaying unit 230 having a screen of large dimensions or of a large number of pixels.

Regarding the display device 200 in the first embodiment of the present invention, the connecting unit 250 is a hinge whereby the carrying unit 240 is hinged to the body 210, so as to achieve the following effects: the body 210 and the carrying unit 240 can rotate toward each other in a book-closing manner or rotate away from each other in a book-opening manner by means of the connecting unit 250; the view of the handheld electronic device 20 and the view of the displaying unit 230 are arranged in a parallel manner or side by side and displayed in the same direction; and the included angle between the body 210 and the carrying unit 240 is adjustable by the connecting unit 250. As shown in FIG. 4, it is desirable to rotate the carrying unit 240 toward the body 210 in a book-closing manner when it is decided that the display device 200 is not to be in use.

Regarding the display device 200 in the first embodiment of the present invention, the fixing unit 260 comprises two clamping members 264. The two clamping members 264 are connected to the adjusting members 262, respectively, for adjusting the two clamping members 264 such that the two clamping members are drawn closer to each other to thereby clamp the handheld electronic device 20. The adjusting members 262 are a pair of racks, rack and gear, or groove and rail, such that the fixing unit 260 can adjust the clamping members 264 to the dimensions of the handheld electronic device 20, thereby allowing the handheld electronic device 20 to be clamped and fixed in place. In addition, the drawings are not restrictive of the quantity of the clamping members 264; hence, there can be four said clamping members 264 arranged rectangularly and adapted to clamp the four sides of the handheld electronic device 20, respectively. A point to note is that the way of clamping the handheld electronic device 20 is illustrated with the preceding embodiment but is not limited thereto; instead, the way of clamping the handheld electronic device 20 can also be snap engagement or any other appropriate means.

Regarding the display device 200 in the first embodiment of the present invention, the transmission of the audiovisual signal between the first transmitting unit 22 and the second transmitting unit 220 is effected by cable transmission. As shown in FIG. 3, in this embodiment, the first transmitting unit 22 of the handheld electronic device 20 comprises a transmission aperture of an HDMI interface and another transmission aperture of a USB interface for transmitting the audiovisual signal or other signals. The second transmitting unit 220 of the display device 200 comprises a transmission jack of an HDMI interface and another transmission jack of a USB interface which are connected to each other by a transmission line to effectuate signal transmission. The types of cable transmission interfaces are not limited to the aforesaid HDMI interface and USB interface but include transmission interfaces such as VGA (Video Graphics Array), DVI (Digital Visual Interface), and DisplayPort.

In addition to cable transmission, transmission between the first transmitting unit 22 and the second transmitting unit 220 can be effected by radio transmission. For example, the display device 200 and the handheld electronic device 20 can comprise a radio transmission interface, such as a Bluetooth interface or an NFC (Near Field Communication) interface, such that a chip of the radio transmission interface is disposed on a circuit board inside the body 210 for receiving the audiovisual signal or other signals from the handheld electronic device 20 and sending the received audiovisual signal or other signals to the handheld electronic device 20 without being connected by a transmission line and a transmission jack

Referring to FIG. 5, there is shown a schematic view of a display device 300 according to the second embodiment of the present invention. A carrying unit 340 of the display device 300 in the second embodiment of the present invention further comprises a receiving chamber 342, a fixing unit 360 disposed in the receiving chamber 342, and a second transmitting unit 320 disposed on a carrying unit 340 and electrically connected to the displaying unit 230. The second transmitting unit 320 is electrically connected to the first transmitting unit 22. The second transmitting unit 320 receives the audiovisual signal, such that the displaying unit 230 can display the audiovisual signal. In this embodiment, the fixing unit 360 comprises an adjusting member 362 and clamping members 364. As shown in FIG. 5, there is just one said clamping member 364, and the clamping member 364 is connected to the adjusting member 362. The adjusting member 362 is a rack or a gear for moving and adjusting the clamping member 364 in a manner that two opposite sides of the handheld electronic device 20 are clamped and fixed in place by the clamping member 364 and a sidewall of the receiving chamber 342, respectively. The second transmitting unit 320, which is exemplified by a transmission jack equipped with a transmission line, is disposed on a sidewall of the receiving chamber 342 and is adapted to be inserted into the first transmitting unit 22 of a transmission aperture having a corresponding transmission interface so as to effectuate electrical connection. In addition, this embodiment and the drawings are not restrictive of the quantity and arrangement of the clamping members 364; instead, the present invention can be exemplified by two said clamping members 364 positioned perpendicular to each other, as shown in FIG. 6, such that the handheld electronic device 20 is jointly clamped and fixed in place by the two clamping members 364 and two adjacent sidewalls of the receiving chamber 342.

Referring to FIG. 7 and FIG. 8, there are shown schematic views of a display device 400 according to the third embodiment of the present invention. Regarding the display device 400 in the third embodiment of the present invention, a connecting unit 450 comprises a first protective panel 452, a bent portion 456, and a second protective panel 454. The body 210 and the carrying unit 240 are disposed on the first protective panel 452 and the second protective panel 454, respectively. The bent portion 456 enables the carrying unit 240 and the body 210 to rotate toward each other or rotate away from each other. For example, the connecting unit 450 is a protective leather case of high rigidity for use with the first protective panel 452 and the second protective panel 454. The bent portion 456 is disposed between the first protective panel 452 and the second protective panel 454, such that the first protective panel 452 and the second protective panel 454 can rotate toward each other in a book-closing manner or rotate away from each other in a book-opening manner. The bent portion 456 further comprises a positioning element or structure for adjusting and fixing the included angle between the first protective panel 452 and the second protective panel 454 so as to adjust the included angle between the body 210 and the carrying unit 240.

Referring to FIG. 9 through FIG. 11, there are shown schematic views of a display device 500 according to the fourth embodiment of the present invention. Regarding the display device 500 in the fourth embodiment of the present invention, a receiving space 512 is disposed on the opposite side of a body 510 relative to the displaying unit 230 and adapted to receive a carrying unit 540. A guiding groove 514 and a sliding element 552 which match each other are disposed in the receiving space 512 and on a connecting unit 550, respectively, for facilitate the sliding of the carrying unit 540 and the sliding of the body 510 relative to each other. Hence, when not in use, the carrying unit 540 can be stored in the receiving space 512. However, when ready to be in use, sliding the sliding element 552 of the carrying unit 540 and the guiding groove 514 in the receiving space 512 relative to each other causes the carrying unit 540 to be pushed out of the receiving space 512. Once the carrying unit 540 is pushed out of the receiving space 512 and the connecting unit 550 lies besides the body 510, the carrying unit 540 and the body 510 can rotate toward each other or rotate away from each other. In this embodiment, for example, the connecting unit 550 is a rod of a hinge structure. Each of the two ends of the rod has the sliding element 552 which matches the guiding groove 514 disposed in the receiving space 512, such that the carrying unit 540 can slide into or out of the receiving space 512.

Referring to FIG. 9 through FIG. 11, the receiving space 512 is disposed on the opposite side of the body 510 relative to the displaying unit 230, such that an opening of the receiving space 512 is formed in the bottom of the body 510 and extends laterally, but this feature does not limit the present invention; as shown in FIG. 12 and FIG. 13, the opening of the receiving space 512 is confined to the lateral side of the body 510 in a manner that the carrying unit 540 can be received and hidden in the receiving space 512.

The display device in the first through fourth embodiments can enlarge and extend the view of a handheld electronic device to the displaying unit, enable the display views of the display device and the handheld electronic device to lie in a parallel manner or side by side when in use and face the user, and enable the display device and the handheld electronic device to rotate toward each other or rotate away from each other. In the scenario where a smartphone functions as the handheld electronic device for an exemplary purpose, it is feasible to treat the handheld electronic device as a keyboard or a touch control input interface to enable the user to employ the handheld electronic device to manipulate input and cause the manipulated view to be displayed on the display device.

Referring to FIG. 14, there is shown a schematic view of signal transmission between the display device and a handheld electronic device according to the fifth embodiment of the present invention. A display device 600 in the fifth embodiment of the present invention is the display device in the first through fourth embodiments and further comprises a touch control unit 670. The touch control unit 670 is disposed on a displaying unit 630 and electrically connected to a second transmitting unit 620 for generating and sending a control signal to the second transmitting unit 620 according to the user's touch control. The handheld electronic device 20 receives the control signal by means of the first transmitting unit 22. Hence, the control signal generated from the touch control unit 670 is outputted by means of the second transmitting unit 620 and then received by the first transmitting unit 22 of the handheld electronic device 20. Hence, it is feasible to control the display device by means of touch control and thereby control the handheld electronic device 20. Furthermore, the signal transmission between the first transmitting unit 22 and the second transmitting unit 620 can be effected by cable transmission or radio transmission.

The display device in the fifth embodiment can enlarge and extend the view of a handheld electronic device to the displaying unit, enable the display views of the display device and the handheld electronic device to lie in a parallel manner or side by side when in use and face the user, and enable the display device and the handheld electronic device to rotate toward each other or rotate away from each other, such that the user can access the touch control function and the display function of the displaying unit and the handheld electronic device concurrently. In the scenario where a smartphone functions as the handheld electronic device for an exemplary purpose, it is feasible to treat the handheld electronic device as a keyboard or a touch control input interface to enable the user to employ the handheld electronic device to manipulate input and cause the manipulated view to be displayed on the display device. Or, alternatively, it is feasible to treat the display device as a keyboard or a touch control input interface in order to meet user needs and meet the requirement for ease of use.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A display device for use with a handheld electronic device having a first transmitting unit, the handheld electronic device outputting at least an audiovisual signal, the display device comprising:
a body;
a displaying unit disposed on a side of the body;
a second transmitting unit disposed on the body and electrically connected to the displaying unit and the first transmitting unit for receiving the audiovisual signal and displaying the audiovisual signal on the displaying unit;
a carrying unit carrying the handheld electronic device and coupled to the body by a connecting unit such that the body and the carrying unit move relative to each other; and
a fixing unit disposed on the carrying unit and comprising at least an adjusting member for adjusting the fixing unit such that the handheld electronic device is fixed in placed by the fixing unit.

2. The display device of claim 1, further comprising a touch control unit disposed on the displaying unit and electrically connected to the second transmitting unit for generating a control signal, wherein the control signal is sent to the handheld electronic device via the second transmitting unit and the first transmitting unit.

3. The display device of claim 1, wherein the connecting unit comprises a first protective panel, a bent portion, and a second protective panel, wherein the body and the carrying unit are disposed on the first protective panel and the second protective panel, respectively, wherein the bent portion enables the carrying unit and the body to rotate toward each other or rotate away from each other.

4. The display device of claim 1, wherein a receiving space is disposed on another side of the body, wherein a guiding groove and a sliding element corresponding in position thereto are disposed at the receiving space and the connecting unit, respectively, for facilitating sliding of the carrying unit and sliding of the body relative to each other.

5. The display device of claim 1, wherein the fixing unit comprises a plurality of clamping members connected to the adjusting member whereby the clamping members are adjusted to approach, clamp, and fix the handheld electronic device.

6. The display device of claim 1, wherein signal transmission between the first transmitting unit and the second transmitting unit is effected by one of cable transmission and radio transmission.

7. A display device for use with a handheld electronic device having a first transmitting unit, the handheld electronic device outputting at least an audiovisual signal, the display device comprising:
a body;
a displaying unit disposed on a side of the body;
a carrying unit carrying the handheld electronic device and coupled to the body by a connecting unit such that the body and the carrying unit move relative to each other;
a second transmitting unit disposed on the carrying unit and electrically connected to the displaying unit and the first transmitting unit for receiving the audiovisual signal and displaying the audiovisual signal on the displaying unit; and
a fixing unit disposed on the carrying unit and comprising at least an adjusting member for adjusting the fixing unit such that the handheld electronic device is fixed in place by the fixing unit.

8. The display device of claim 7, further comprising a touch control unit disposed on the displaying unit and electrically connected to the second transmitting unit for generating a control signal, wherein the control signal is sent to the handheld electronic device via the second transmitting unit and the first transmitting unit.

9. The display device of claim 7, wherein the fixing unit comprises a plurality of clamping members connected to the adjusting member and adapted to adjust the clamping members such that clamping members are drawn closer to each other to thereby clamp and fix the handheld electronic device in place.

10. The display device of claim 7, wherein the carrying unit further comprises a receiving chamber such that the fixing unit is received in the receiving chamber.

11. The display device of claim 7, wherein signal transmission between the first transmitting unit and the second transmitting unit is effected by one of cable transmission and radio transmission.
